(19) United States
(12) Patent Application Publication
(10) Pub. No.: US 2026/0247762 A1
(43) Pub. Date: Aug. 20, 2026

(54) USE OF KSF PHOSPHOR IN LEDS WITH WIRE-BONDS WITH MAXIMUM AMOUNT OF SILVER

(71) Applicant: SIGNIFY HOLDING B.V., EINDHOVEN (NL)

(72) Inventors: RENÉ THEODORUS WEGH, VELDHOVEN (NL); XIAO Ye HU, NANJING (CN)

(21) Appl. No.: 18/872,357

(22) PCT Filed: Jun. 6, 2023
(86) PCT No.: PCT/EP2023/065034

§ 371 Date: Dec. 6, 2024

(30) Foreign Application Priority Data
Jun. 8, 2022 (WO) PCT/CN2022/097703
Jun. 28, 2022 (EP) 22181664.8

(51) Int. Cl. H10H 20/851; H10H 20/856

(52) U.S. Cl. CPC H10H 20/8513; H10H 20/856

(57) ABSTRACT

The invention provides a light generating device (100) configured to provide device light (101), wherein the light generating device (100) comprises: (A) a light source (10) configured to provide light source light (11), wherein the light source (10) comprises a solid state light source (15); (B) a support (400) comprising an electrical conductor (405); wherein the support (400) is configured to support the light source (10); (C) a wire bonding (410) configured to provide an electrical connection between the solid state light source (15) and the electrical conductor (405), wherein the wire bonding (410) comprises 1-40 wt % Ag; (D) a luminescent element (200) configured in contact with the solid state light source (15) and the wire bonding (410); wherein the luminescent element (200) comprises a first luminescent material (210), configured to convert at least part of the light source light (11) into first luminescent material light (211), wherein the first luminescent material (210) comprises M′ₓM₂₋₂ₓ₋AX₆ doped with tetravalent manganese, wherein M′ comprises an alkaline earth cation, wherein M comprises a cation, and x is in the range of 0-1, wherein A comprises a tetravalent cation, wherein X comprises a monovalent anion, at least comprising fluorine; and (E) wherein the device light (101) comprises the first luminescent material light (211).

### FIELD OF THE INVENTION

The invention relates to a light generating device. The invention further relates to a lighting device comprising such light generating device.

### BACKGROUND OF THE INVENTION

The use of wire bonding containing silver (Ag) in semiconductor light emitting devices is known in the art. US20171489631A1, for instance, describes a bonding wire for a semiconductor package and a semiconductor package including the same. The bonding wire for the semiconductor package may include a core portion including silver (Ag), and a shell layer surrounding the core portion, having a thickness of 2 nm to 23 nm, and including gold (Au). The semiconductor package may include a package body having a first electrode structure and a second electrode structure, a semiconductor light emitting device comprising a first electrode portion and a second electrode portion electrically connected to the first electrode structure and the second electrode structure, and a bonding wire connecting at least one of the first electrode structure and the second electrode structure to the semiconductor light emitting device.

### SUMMARY OF THE INVENTION

There is a continuous drive for better energy efficiency of illumination products and therefore of light emitting diodes (LEDs). Regulations such as the new energy labels in Europe and DLC5.1 in NAM stimulate the push for ever higher efficiency. A significant efficiency step may be possible with the use of a phosphor material able to convert light to a narrow-band red light. This is starting to be applied in standard LED packages with lateral dies for color rendering index (CRI) of at least 90, which may lead to efficiency gains over 10%. Mn-doped fluorides such as potassium hexafluoro silicate (K₂SiF₆:Mn, abbreviated as KSF, wherein Mn is tetravalent) is one such promising narrow-band red phosphor candidate that may have high efficiency gains, which is already being applied in various LED types and application conditions.

However, the reliability of KSF, and other luminescent materials within the family to which KSF belongs, may not be optimal leading to limitations on application conditions, such as power, temperature, and humidity. One of the failure modes in KSF-containing LEDs may be degradation. This may lead to flux decay and potentially catastrophic failure in conditions where the temperature becomes too high in areas with degraded KSF. In KSF-containing LEDs, degradation appeared to occur in storage tests under high humidity and high temperature conditions and was accelerated by light exposure.

Hence, it is an aspect of the invention to provide an alternative light generating device, which preferably further at least partly obviates one or more of above-described drawbacks. The present invention may have as object to overcome or ameliorate at least one of the disadvantages of the prior art, or to provide a useful alternative.

In a first aspect, the invention provides a light generating device configured to provide device light. In embodiments, the light generating device may comprise a light source. The light source may be configured to provide light source light. Especially, the light source may comprise a solid state light source. In embodiments, the light generating device may comprise a support. The support may comprise an electrical conductor. Further, the support may be configured to support the light source. In embodiments, the light generating device may comprise a wire bonding. The wire bonding may be configured to provide an electrical connection between the solid state light source and the electrical conductor. Especially, the wire bonding may comprise 1-40 wt % Ag. In embodiments, the light generating device may comprise a luminescent element. The luminescent element may be configured in contact with the solid state light source and the wire bonding. Further, the luminescent element may comprise a first luminescent material. The first luminescent material may be configured to convert at least part of the light source light into first luminescent material light. Especially, the first luminescent material may comprise M′ₓM₂₋₂ₓAX₆ doped with tetravalent manganese: wherein M′ may comprise an alkaline earth cation; wherein M may comprise an (alkaline) cation, and x may be in the range of 0-1; wherein A may comprise a tetravalent cation, which may at least comprise silicon; wherein X may comprise a monovalent anion, which may at least comprise fluorine. In embodiments, the device light may comprise the first luminescent material light. Therefore, in embodiments the invention provides a light generating device configured to provide device light, wherein the light generating device comprises: a light source configured to provide light source light, wherein the light source comprises a solid state light source; a support comprising an electrical conductor; wherein the support is configured to support the light source; a wire bonding configured to provide an electrical connection between the solid state light source and the electrical conductor, wherein the wire bonding comprises 1-40 wt % Ag; a luminescent element configured in contact with the solid state light source and the wire bonding; wherein the luminescent element comprises a first luminescent material, configured to convert at least part of the light source light into first luminescent material light, wherein the first luminescent material comprises M′ₓM₂₋₂ₓAX₆ doped with tetravalent manganese, wherein M′ comprises an alkaline earth cation, wherein M comprises an (alkaline) cation, and x is in the range of 0-1, wherein A comprises a tetravalent cation, in specific embodiments at least comprising silicon, wherein X comprises a monovalent anion, at least comprising fluorine; and wherein the device light comprises the first luminescent material light.

With the present invention, the light generating device may provide a KSF-containing LED which appears surprisingly less susceptible or substantially not susceptible to degradation, even under conditions such as temperature, humidity, and light exposure. Hence, such a light generating device may comprise KSF as a narrow-band red phosphor candidate that may have high efficiency gains and an advantageous effect on CRI and/or R9, but may avoid the potential efficacy and safety issues associated with blackening in KSF-containing LEDs. Blackening is one of the failure modes in KSF-containing LEDS: certain areas in the phosphor-containing compartments may become dark. This may lead to flux decay and potentially failure in conditions where the temperature becomes too high in blackened areas due to absorption of light. This may not only apply to KSF, but also to related materials (e.g. of the same family and having the M′ₓM₂₋₂ₓAX₆ formula).

As indicated, the invention provides a light generating device. A light generating device (or “lighting device”) may be configured to generate light generating device light (or “device light”). The term “light generating device” may also refer to a plurality of light generating devices which may provide device light having essentially the same spectral power distributions. In specific embodiments, the term “light generating device” may also refer to a plurality of light generating devices which may provide device light having different spectral power distributions.

Especially, the term “light” may refer to (at least) visible light. The terms “visible”, “visible light” or “visible emission” and similar terms refer to light having one or more wavelengths in the range of about 380-780 nm.

In embodiments, the light generating device may comprise a light source. The term “light source” may also relate to a plurality of light sources, such as for example 2-200 (solid state) LED light sources. The light source may especially be configured to generate light source light. In embodiments, the device light may essentially consist of the device light. In other embodiments, the device light may essentially consist of converted light source light. In yet other embodiments, the device light may comprise (unconverted) light source light and converted light source light. Light source light may be converted with a luminescent material into luminescent material light and/or with an upconverter into upconverted light. The device light may especially in embodiments comprise one or more of light source light and converted light source light (such as luminescent material light).

Especially, the light source may comprise a solid state light source in embodiments. The term “solid state light source”, or “solid state material light source”, and similar terms, may especially refer to semiconductor light sources, such as a LED, a diode laser, or a superluminescent diode. In a specific embodiment, the light source comprises a solid state LED light source (such as a LED or laser diode (or “diode laser”)). The term LED may also refer to a plurality of LEDs.

The light source may have a light escape surface. For LEDs it may for instance be the LED die, or when a resin is applied to the LED die, the outer surface of the resin. In principle, it may also be the terminal end of a fiber. The term escape surface especially relates to that part of the light source, where the light actually leaves or escapes from the light source. The light source is configured to provide a beam of light. This beam of light (thus) escapes from the light exit surface of the light source.

Likewise, a light generating device may comprise a light escape surface, such as an end window. Further, likewise a light generating system may comprise a light escape surface, such as an end window.

In embodiments, the light source may comprise one or more micro-optical elements (array of micro lenses) downstream of a single solid-state light source, such as a LED, or downstream of a plurality of solid-state light sources (i.e. e.g. shared by multiple LEDs). In embodiments, the light source may comprise a LED with on-chip optics. In embodiments, the light source comprises a pixelated single LED (with or without optics) (offering in embodiments on-chip beam steering).

The light source may especially be configured to generate light source light having an optical axis (O), (a beam shape,) and a spectral power distribution. The light source light may in embodiments comprise one or more bands, having band widths as known for lasers.

Especially, the light source may be a light source that during operation emits light source light at a wavelength selected from the range of 200-490 nm, especially a light source that during operation emits at least light at wavelength selected from the range of 400-490 nm, even more especially in the range of 440-490 nm. This light may partially be converted into different types of light (see further also below).

In embodiments, the light generating device may comprise a support. Further, in embodiments the support may comprise multiple components from different materials. In specific embodiments, the support may mostly consist of a monolithic body from a single material with small parts of different materials passing through and past the monolithic body. In other embodiments, the support may consist of a stack or laminate of different materials. Herein, the term “contact” or “in contact”, and similar terms, may especially refer in embodiments to physical contact. For instance, the layers or layer elements that are in contact may adhere to each other, as known in the art of e.g. semiconductor LEDs.

Especially, in embodiments the support may comprise an electrical conductor. Such an electrical conductor may be a material that facilitates electrical contact between electrically conductive elements. Instead of the term “electrical contact”, and similar terms, also the terms “electrical conductive contact” or “electrically conductive contact”, and similar terms, may be used. When two (or more) elements have an electrical conductive connection, then there may be a conductivity (at room temperature) between the two (or more) elements of at least 1·10⁵ S/m, such as at least 1·10⁶ S/m. In general, an electrically conductive connection will be between two (or more) elements each comprising an electrically conductive material, which may be in physical contact with each other or between which an electrically conductive material is configured. Herein a conductivity of an insulated material may especially be equal to or smaller than 1·10⁻¹⁰ S/m, especially equal to or smaller than 1·10⁻¹³ S/m. Herein a ratio of an electrical conductivity of an isolating material (insulator) and an electrical conductivity of an electrically conductive material (conductor) may especially be selected smaller than 1·10⁻¹⁵.

An electrically conductive element may comprise, or essentially consist of electrically conductive material. An electrically insulating element may comprise, or essentially consist of electrically insulating material. Herein, in embodiments a conductive material may especially comprise a conductivity (at room temperature) of at least 1·10⁵ S/m, such as at least 1·10⁶ S/m. Herein, a conductivity of an insulated material may especially be equal to or smaller than 1·10⁻¹⁰ S/m, especially equal to or smaller than 1·10⁻¹³ S/m. Herein a ratio of an electrical conductivity of an isolating material (insulator) and an electrical conductivity of an electrically conductive material (conductor) may especially be selected smaller than 1·10⁻¹⁵.

An electrically conductive contact may refer to a (physical) contact between two (or more) electrically conductive elements, such as between an electrical conductor and an electrically conductive wire bonding. When in embodiments the electrical conductivity of the arrangement of the two conductive elements measured over the two conductive elements be at least 1·10⁶ S/m, then there is electrically conductive contact. It may also refer in specific embodiments to an arrangement of two (or more) electrically conductive elements with a medium in between. When in embodiments the electrical conductivity of the arrangement of the two conductive elements measured over the two conductive elements with the medium in between, be at least 1·10⁶ S/m, then there is also electrically conductive contact.

In embodiments, electrical conductors may comprise a layer element. The term “electrically conductive track” may be used to referrer to such an electrically conductive layer element.

An electrical conductor may comprise a metal material. For instance, in embodiments the metal layer may be an aluminum layer. Instead of (or in addition to) aluminum, the metal material may comprise a copper material. For instance, in embodiments the metal layer may be a copper layer. Other solutions may also be possible, like stainless steel, other metals, or (their) metal alloys. Especially, the electrical conductor may comprise a metal core of the support. The electrical conductor may be available over essentially the entire support. In other embodiments, the electrical conductor may be available over only part of the support.

In embodiments, an external electricity source may provide a (constant) electric current to the electrically conductive elements of the system via electrically conductive wires that may be inserted into electrically conductive connector units. Such connector units may facilitate the delivery of a constant electric current to the electrical conductor and the light source. Especially, such connector units may be placed on the same electrically conductive copper layer comprised by the electrical conductor comprised by the support and deliver the constant electric current through the electrical conductor.

Hence, the electrical conductor may facilitate delivery of the constant electric current from the external electricity source to the light generating device.

Further, the support may be configured to support the light source. It may hence provide a support function and may have a thermal dissipation function and/or a thermal spread function.

Especially, the support may comprise a PCB. As known in the art, a printed circuit board (“PCB” or “board”) may mechanically support and electrically connect electronic components or electrical components using electrically conductive tracks, pads and other features etched from one or more sheet layers of copper laminated onto and/or between sheet layers of a non-conductive substrate (shortly indicated as “track” or “conductive track”); though other options may also be possible.

A PCB may comprise one or more electrically conductive tracks, which may e.g. comprise copper. When there are two or more electrically conductive tracks, two or more tracks may be electrically isolated from each other. In embodiments, two or more electrically conductive tracks may be electrically isolated from each other, but be (temporarily) electrically connected to each other via one or more electrical component. The electrical connection may be temporary, when e.g. during operation a switch opens or closes an electrical connection. An electrical connection may e.g. be permanent, when e.g. an electrical component is configured electrically connected to two electrically conductive tracks.

Hence, in embodiments a PCB may comprise an insulating layer arranged between a substrate and a conductive layer.

An (electronic) component, such as a solid stage light source, may generally be soldered onto the PCB to both electrically connect and mechanically fasten it to the PCB. For instance, a basic PCB may consist of a flat sheet of insulating material and a layer of copper foil, laminated to the substrate. Chemical etching divides the copper into separate conducting lines called tracks or circuit traces, pads for connections, vias to pass connections between layers of copper, and features such as solid conductive areas for EM shielding or other purposes. The tracks function as wires fixed in place, and are insulated from each other by air and the board substrate material. The surface of a PCB may have a coating that protects the copper from corrosion and reduces the chances of solder shorts between traces or undesired electrical contact with stray bare wires. For its function in helping to prevent solder shorts, the coating is called solder resist.

Hence, the shape of a PCB may in general be plate-like. Especially, in embodiments the PCB may have a length and a width and a height, wherein an aspect ratio of the length and the height is at least 5, like in the range of 5-5000, like 10-2500, and wherein an aspect ratio of the width and the height is at least 2, such as an aspect ratio of at least 5, like in the range of 5-5000, like 10-2500. The terms “length”, “width”, and “height” may also refer to “largest length”, “largest width”, and “largest height”, respectively. The PCB may especially have a rectangular cross-section (such as a square cross-section).

The height (or thickness) of the PCB may in embodiments be selected from the range of 0.2-10 mm, such as 0.5-5 mm, like 1-2 mm. The width of the PCB may in embodiments be selected from the range of 5-200 mm, such as 5-50 mm. The length of a single printed circuit board area may in embodiments e.g. be selected from the range of 10-50 mm, such as 15-40 mm. The length of the PCB, including a plurality of (connected) PCB areas, may in embodiments e.g. be selected from the range of 20-2000 mm, such as 20-1500 mm. Other dimensions may be possible as well.

In further embodiments, the functional component may comprise an electronic component, especially an electronic component selected from the group comprising a solid state light source, a driver, an electronic module, or a sensor. Especially, the electronic component may comprise a solid state light source.

In embodiments, the board may comprise a rigid board or a semi-rigid board, especially a rigid board. In other embodiments, the board may comprise a semi-rigid board. In specific embodiments, the printed circuit may be flexible. In yet other embodiments, the printed circuit board may be rigid.

In embodiments, the board may comprise a metal, especially a metal selected from the group comprising copper aluminum, tin, iron, silver and lead, more especially a metal selected from the group comprising copper and aluminum.

In further embodiments, the (printed circuit) board may have a thermal conductivity of at least 200 W/(m*K), especially at least 250 W/(m*K), such as at least 300 W/(m*K).

In specific embodiments, the board may comprise a printed circuit board. Especially, the board may comprise one or more of a CEM-1 PCE, a CEM-3 PCE, a FR-1 PCE, a FR-2 PCB, a FR-3 PCB, a FR-4 PCB, and aluminum metal core PCB, especially one or more of a CEM-1 PCB, a CEM-3 PCB, a FR-1 PCB, and a FR4 PCB and an aluminum metal core PCB, more especially one or more of a CEM-1 PCB, a CEM-3 PCB, a FR-1 PCB.

In embodiments the printed circuit board comprises a thermally conductive material, such as aluminum. Printed circuit boards comprising a metal core may also be indicated as insulated metal substrate (IMS).

The substrate may also be based on highly flexible printed electronics where electronic circuitry is printed on substrates such as PET and polyimide films.

In embodiments, the light generating device may comprise a wire bonding. The wire bonding may be configured to provide an electrical connection between the solid state light source and the electrical conductor. Hence, the wire bonding may facilitate delivery of an electric current from the external electricity source to the light source via the electrical conductor (during operation of the solid state light source).

Surprisingly, wire bonding comprising Ag in weight percentage of about 50% or lower, more especially 40% or lower, appeared to provide luminescent material comprising light generating devices that are less or not susceptible to luminescent material degradation under conditions such as temperature, humidity, and light exposure, at least especially in relation to the M′ₓM₂₋₂ₓAX₆ doped with tetravalent manganese luminescent material. In embodiments, the wire bonding may comprise 1-40 wt % Ag. Hence, a wire bonding may be provided that contains low weight percentages of Ag. Therefore, embodiments with such wire bonding may substantially not lead to degradation of the M′ₓM₂₋₂ₓAX₆ doped with tetravalent manganese luminescent material.

However, Ag remains a desired metal for wire bonding, being electrically conductive and relatively cheap compared to other metals used for wire bonding, e.g. gold (Au), and providing a good reflectance for visible light. As the use of Ag in wire bonding may be relatively safe in weight percentages below 40 wt %, it may be cost-effective and desirable from a reflectively point of view to increase the amount of Ag in wire bonding to a weight percentage above 0 wt %. Hence, the wire bonding may comprise especially 5-40 wt % Ag, more especially 20-40 wt % Ag, to facilitate a good balance between stability of the light generating device (in respect to optical properties) and reflectivity of the wire bonding (and thus efficiency).

In embodiments, the wire bonding may be a metal alloy comprising at least 60 wt % Au. Au may be the preferable metal to substitute high concentrations of Ag in metal components of the light generating device, as it is electrically conductive and may not react with KSF leading to degradation. However, Au is more expensive than Ag, and as described above, it may in embodiments be desirable to use as high a concentration of Ag as can be applied safely. Hence, the wire bonding may be an alloy comprising 1-40 wt % Ag, with the rest of the alloy material comprising 60-99 wt % Au. Especially, the wire bonding may comprise 5-40% wt % Ag, with the rest of the alloy material comprising 60-95 wt % Au. More especially, the wire bonding may comprise 20-40% wt % Ag, with the rest of the alloy material comprising 60-80 wt % Au. In specific embodiments, the alloy may also include concentrations of other metal materials, e.g. one or more of copper, aluminum, magnesium, and beryllium, up to about 5 wt % or more of the wire bonding.

As indicated above, in embodiments the light generating device may comprise a luminescent element. The luminescent element comprises at least a first luminescent material (see also below). In embodiments, the luminescent element may comprise a luminescent layer. Alternatively or additionally, the luminescent element may comprise a polymeric material wherein the luminescent material is embedded. The luminescent element may comprise a luminescent body, like a ceramic body, or a polymeric body (such as in embodiments a polymeric dome).

Especially, the luminescent element is configured in a light receiving relationship with the light source. The luminescent element is especially radiationally coupled with the light source. The terms “light-receiving relationship” or “light receiving relationship”, and similar terms, may indicate that an item may during operation of a source of light (like a light generating device or light generating element or light generating system) may receive light from that source of light. Hence, the item may be configured downstream of that source of light. Between the source of light and the item, optics may be configured. The terms “upstream” and “downstream”, such as in the context of propagation of light, may especially relate to an arrangement of items or features relative to the propagation of the light from a light generating element (here the especially the (solid state) light source), wherein relative to a first position within a beam of light from the light generating element, a second position in the beam of light closer to the light generating element (than the first position) is “upstream”, and a third position within the beam of light further away from the light generating element (than the first position) is “downstream”. For instance, instead of the term “light generating element” also the term “light generating means” may be applied. The terms “radiationally coupled” or “optically coupled” or “radiatively coupled” may especially mean that (i) a light generating element, such as a light source, and (ii) another item or material, are associated with each other so that at least part of the radiation emitted by the light generating element is received by the item or material. In other words, the item or material is configured in a light-receiving relationship with the light generating element. At least part of the radiation of the light generating element will be received by the item or material. This may in embodiments be directly, such as the item or material in physical contact with the (light emitting surface of the) light generating element. This may in embodiments be via a medium, like air, a gas, or a liquid or solid light guiding material. In embodiments, also one or more optics, like a lens, a reflector, an optical filter, may be configured in the optical path between light generating element and item or material. The term “in a light-receiving relationship” does, as indicated above, not exclude the presence of intermediate optical elements, such as lenses, collimators, reflectors, dichroic mirrors, etc. In embodiments, the term “light-receiving relationship” and “downstream” may essentially be synonyms.

The luminescent element may be configured in contact with the solid state light source and the wire bonding. Hence, in this way part of the first luminescent material may be configured close to the wire bonding or even in physical contact with the wire bonding.

Therefore, in embodiments the luminescent element may comprise a polymeric host matrix element (“host” or “matrix” or “polymeric matrix”. The term “polymeric host matrix element” refers to the polymeric host as well as the optional one or more non-host materials hosted by the polymeric host. Hence, herein the polymeric host matrix element comprises a polymeric host wherein the first outer layer comprises polymeric host material that may host a first luminescent material (described further below) and that may host one or more other materials (such as a second luminescent material, a scattering material, etc.), but which may in embodiments essentially consist of the polymeric material (and thus effectively not having a hosting function), and a remaining part comprising polymeric host material hosting the first luminescent material and optionally hosting one or more other materials (such as a second luminescent material, a scattering material, etc.).

The luminescent element comprises the polymeric host matrix element and optionally one or more other elements, such as e.g. a layer, such as an optical layer, on the polymeric host matrix element (downstream of the polymeric host matrix element, such as on the first outer face), or a layer between a light emitting surface of the light source and the polymeric host matrix element (polymeric host matrix element), and/or a reflective layer, etc. Hence, in embodiments, in addition to the polymeric host matrix element the converter element may include other elements, such as optically functional layers.

The polymeric host matrix element especially comprises a light transmissive material, i.e. transmissive for the light source light and the converter light. Amongst others, especially silicones may be useful (as host matrix material). Hence, the host matrix may especially comprise a polysiloxanes host material. Polysiloxanes for LED applications are well known in the art. Polysiloxanes may herein also be indicated as “silicone”. Suitable materials are commercially available, and are e.g. also known as “silicone encapsulants”. Alternatively or additionally, the light transmissive material (for the host) may comprise an epoxy (material). Other light transmissive encapsulants may also be possible, like e.g. epoxy, polycarbonate, or PMMA (polymethylmethacrylate). A combination of two or more different materials as encapsulant may also be possible. The encapsulant may especially enclose a light emitting surface of a (solid state) light source.

In embodiments, the luminescent element may comprise a polymeric layer with luminescent material embedded therein. In (other) embodiments, the luminescent element may comprise an inorganic material layer comprising the luminescent material, optionally also comprising a binder material. Such layers may e.g. be provided via known coating technologies. In (yet other) embodiments, the luminescent element may comprise a ceramic body.

In embodiments, the luminescent element may comprise a first luminescent material, especially, a Mn(IV) (“tetravalent manganese”) type luminescent material. Hence, in an embodiment the first luminescent material comprises a (red) luminescent material selected from the group consisting of Mn(IV) luminescent materials, even more especially the first luminescent material comprises a luminescent material of the type M′ₓM₂₋₂ₓAX₆ doped with tetravalent manganese: wherein M′ may comprise an alkaline earth cation; wherein M may comprise an (alkaline) cation, and x may be in the range of 0-1; wherein A may comprise a tetravalent cation, which may in specific embodiments at least comprise silicon; wherein X may comprise a monovalent anion, which may at least comprising Fluorine (F). M relates to monovalent cations, such as selected from the group consisting of potassium (K), rubidium (Rb), lithium (Li), sodium (Na), cesium (Cs) and ammonium (NH₄⁺), and especially M comprises at least one or more of K and Rb. Preferably, at least 80%, even more preferably at least 90%, such as 95% of M consists of potassium and/or rubidium. The cation A may comprise one or more of silicon (Si) titanium (Ti), germanium (Ge), stannum (Sn) and zinc (Zn). Preferably, at least 80%, even more preferably at least 90%, such as at least 95% of A consists of silicon and/or titanium and/or germanium (not taking into account the partial replacement by Mn⁴⁺).

Relevant alkaline earth cations (M′) are magnesium (Mg), strontium (Sr), calcium (Ca) and barium (Ba). In an embodiment, a combination of different alkaline cations may be applied. In yet another embodiment, a combination of different alkaline earth cations may be applied. In yet another embodiment, a combination of one or more alkaline cations and one or more alkaline earth cations may be applied. In embodiments, x may thus be in the range of 0-1, especially x<1. In an embodiment, x=0.

Especially, M comprises potassium and A comprises silicon. X relates to a monovalent anion, but especially at least comprises fluorine. Other monovalent anions that may optionally be present may be selected from the group consisting of chlorine (Cl), bromine (Br), and iodine (I). Preferably, at least 80%, even more preferably at least 90%, such as 95% of X consists of fluorine. The term “tetravalent manganese” refers to Mn⁴⁺. This is a well-known luminescent ion. In the formula as indicated above, part of the tetravalent cation A (such as Si) is being replaced by manganese. Hence, M₂AX₆ doped with tetravalent manganese may also be indicated as M₂A₁₋ₘMnₘX₆. The mole percentage of manganese, i.e. the percentage it replaces the tetravalent cation A will in general be in the range of 0.1-15%, especially 1-12%, i.e. m is in the range of 0.001-0.15, especially in the range of 0.01-0.12. Further embodiments may be derived from WO2013/088313, which is herein incorporated by reference.

Hence, in an embodiment the first luminescent material comprises M₂AX₆ doped with tetravalent manganese, wherein M comprises an alkaline cation, wherein A comprises a tetravalent cation, and wherein X comprises a monovalent anion, at least comprising fluorine. Even more especially, wherein M comprises at least one or more of K and Rb, wherein A comprises one or more of Si and Ti, and wherein X=F. An example of a suitable first luminescent material is e.g. K₂SiF₆:Mn (5%) (i.e. K₂Si₍₁₋ₓ₎MnₓF₆, with x=0.05). Here, M is substantially 100% K, A is substantially 100% Si, but with a replacement thereof with 5% Mn (thus effectively 95% Si and 5% Mn), and X is substantially 100% F. In specific embodiments, M is essentially K. Such luminescent material may especially emit in the red, due to the tetravalent manganese. The term “first luminescent material” may also refer to a plurality of different first luminescent materials of the type M₂AX₆ doped with tetravalent manganese, such as e.g. K₂SiF₆:Mn and/or K₂TiF₆:Mn. In embodiments, M comprises potassium and A comprises silicon. Hence, in embodiments the particulate first luminescent material comprises K₂SiF₆ doped with tetravalent manganese. Note that when there are different first luminescent materials, the weight percentage and/or y/x ratios relate to each type of first luminescent material, respectively. Hence, in specific embodiments the first luminescent material may comprise Mn comprising M₂(Si,Ti)X₆, more especially Mn comprising K₂(Si,Ti)F₆, wherein “Si,Ti” refers to one or more of Si and Ti. First luminescent materials may also be selected from the group of K₂[SiF₆]:Mn⁴⁺, Na₂[SiF₆]:Mn⁴⁺, K₂[TiF₆]:Mn⁴⁺, Ba[TiF₆]:Mn⁴⁺, K₂[SnF₆]:Mn⁴⁺, Na₂[TiF₆]:Mn⁴⁺, KRb[TiF₆]:Mn⁴⁺ and K₂[Si_{0.5}Ge_{0.5}F₆]:Mn⁴⁺, though further options may also be possible.

The first luminescent material may be configured to convert at least part of the light source light into first luminescent material light. In embodiments, the device light may comprise the first luminescent material light. In specific embodiments, the light source may be configured to provide light source light and part of the light source light is converted into secondary light. Secondary light may be based on conversion by the luminescent material. The secondary light may therefore also be indicated as luminescent material light.

As indicated above, the luminescent material may be Mn⁴⁺ based, which may emit in the red. In a specific embodiment, the first luminescent material is configured to convert blue light into red light. Hence, the solid state light source may be configured to provide blue light source light, which may at least partly be converted by the first luminescent material. Especially, as described above, in embodiments, M′ₓM₂₋₂ₓAX₆ may comprise K₂SiF₆.

In embodiments, the luminescent element may comprise at least 2 wt % of the first luminescent material, more especially 5-60 wt % of the first luminescent material. Especially, the first luminescent material is a particulate first luminescent material. Good results may be obtained with relatively large particles. Hence, in embodiments the particulate first luminescent material has a volume averaged particle size selected from the range of 5-50 μm, such as especially 10-40 μm, such as more especially a volume averaged particle size selected from the range of 15-40 μm. In embodiments, the particulate first luminescent material has a d50 value selected from the range of 5-50 μm, such as especially 10-40 μm, such as more especially 15-40 μm, like in the range of 20-35 μm. Further, especially at least 50 wt %, such as at least 80 wt % of the first luminescent material particles have particle sizes within the range of 10-40 μm, especially within the range of 15-40 μm, even more especially in the range of 20-35 μm. Further, when other luminescent materials are available in the host matrix (see also below), their volume averaged particle sizes are especially smaller, such as below in the range of about 7-20 μm. However, the volume averaged particle size may also be larger.

In embodiments, the particulate first luminescent material is available in the polymeric host matrix element with an average weight percentage x averaged over the polymeric host matrix element. Hence, the weight relates to the total weight of the polymeric host matrix element, including the polymeric material, the first luminescent material, and optionally other materials that are available in the host (like a second luminescent material and/or scattering particles, etc.). Hence, assuming by way of example polymeric material of the host matrix to be 90 parts, and the first luminescent material in the host matrix to be 10 parts, and no other materials in the polymeric host matrix element, the weight percentage x of the first luminescent material is 10 wt %. The weight percentage x thus refers to a bulk weight. The precise weight percentage may depend on the thickness of the matrix, the spectral distribution of the light source light (which is used as excitation light by the luminescent material), the desired color point, the availability of other luminescent materials and/or scattering elements in the matrix, etc. In embodiments, the host matrix may comprise one or more of silicone, epoxy, polycarbonate, and PMMA (polymethylmethacrylate)).

In embodiments, the luminescent element may comprise a light transmissive layer, such as a light transmissive dome. This light transmissive dome may itself comprise the polymeric host matrix element and the first luminescent material. Such a dome shape may facilitate shaping the light beam of the light generating device evenly in all directions of a 180° area. Hence, downstream light beam shaping in a larger light generating system may be used to further shape the light beam.

In other embodiments, the luminescent element may instead be a light transmissive element contained within one or more (support) dams. Such a light transmissive element may itself comprise the polymeric host matrix element and the first luminescent material embedded therein. However, also an inorganic host matrix element and the first luminescent material embedded therein may be applied. Yet other luminescent elements may also be possible (see also above). Such a luminescent element contained within one or more (support) dams may facilitate shaping the light beam of the light generating device in a direction from the light generating device. Especially, the support dam may be reflective. Hence, in embodiments, the luminescent element may be configured in a reflector cup. The one or more (support) dams may comprise a white reflective, such as a polymeric white reflective material.

In specific embodiments, the light generating device may comprise a chip-on-board light generating device. Such a chip-on-board light generating device may comprise the (solid state) light source, especially a plurality of (solid state) light sources. In embodiments, the light generating device may comprise a luminescent layer comprising the luminescent material configured downstream of the chip-on-board light generating device. In other embodiments, the luminescent layer may be spread over a plurality of LEDs, e.g. over all or at least part of a chip comprised by the chip-on-board light generating device. Such luminescent layer may e.g. be applied over the chip(s) (or PCB) by one or more of dispensing, jetting, or spray-coating. Such luminescent layer may cover the (solid state) light sources and also the support, supporting the (solid state) light sources. Hence, such luminescent element may be in contact with the wire bonding(s).

Such a chip-on-board light generating device especially refers to LED chips in the form of a semiconductor chip that is neither encased nor connected but directly mounted onto a substrate, such as a printed circuit board or “PCB”. Hence, a plurality of light emitting semiconductor light source may be configured on the same substrate. In embodiments, a chip-on-board light generating device is a multi LED chip configured together as a single lighting module.

In embodiments, the light source and the first luminescent material may be configured such that part of the light source light escapes from the light generating device. Such light source light may be comprised by the device light without being converted by the first luminescent material. Hence, in embodiments, the light generating device may be configured to generate device light comprising the light source light and the first luminescent material light. Hence, in embodiments the luminescent element may be configured to partly convert the light source light into luminescent material light.

Especially, in embodiments, the light source light may have one or more wavelengths in the blue wavelength range. Further, the first luminescent material light may have one or more wavelengths in the red wavelength range.

In order to obtain white light, the light generating device may comprise one or more other luminescent materials and/or the light generating device may comprise further (solid state) light sources. Herein, especially the former is described. Hence, in embodiments the luminescent element may comprise in addition to the Mn⁴⁺ based luminescent material, one or more other luminescent materials, which may have spectral intensity in one or more of the blue, cyan, green, yellow, orange, and red, especially having centroid wavelengths in one of the green, yellow, and orange, respectively. The one or more other luminescent materials may also be configured to convert at least part of the light source light. Embodiments of luminescent materials are further described below.

The terms “violet light” or “violet emission” especially relates to light having a wavelength in the range of about 380-440 nm. The terms “blue light” or “blue emission” especially relates to light having a wavelength in the range of about 440-495 nm (including some violet and cyan hues). The terms “green light” or “green emission” especially relate to light having a wavelength in the range of about 495-570 nm. The terms “yellow light” or “yellow emission” especially relate to light having a wavelength in the range of about 570-590 nm. The terms “orange light” or “orange emission” especially relate to light having a wavelength in the range of about 590-620 nm. The terms “red light” or “red emission” especially relate to light having a wavelength in the range of about 620-780 nm. The term “pink light” or “pink emission” refers to light having a blue and a red component. The term “cyan” may refer to one or more wavelengths selected from the range of about 490-520 nm. The term “amber” may refer to one or more wavelengths selected from the range of about 585-605 nm, such as about 590-600 nm.

In further embodiments, the luminescent element may comprise a second luminescent material. The second luminescent material may be different from the first luminescent material, and may be configured to convert at least part of the light source light into second luminescent material light. In embodiments, the device light may comprise the first luminescent material light and the second luminescent material light. The luminescent element may comprise 5-60 wt % of the second luminescent material, as has been described similarly for the first luminescent material above.

The second luminescent material light may have one or more wavelengths in the green-yellow wavelength range. The second luminescent material may comprise a luminescent material of the type A₃B₅O₁₂:Ce, wherein A comprises one or more of Y, La, Gd, Tb and Lu, and wherein B comprises one or more of Al, Ga, In and Sc (see further also below). Especially in such embodiments, the luminescent element may comprise 5-60 wt % of the second luminescent material.

In embodiments, the light source, the first luminescent material, and the second luminescent material may be configured such that part of the light source light escapes from the light generating device comprised by the device light without being converted by the first luminescent material or the second luminescent material. The light generating device may be configured to generate device light comprising the light source light, the first luminescent material light, and the second luminescent material light.

Especially, in embodiments, the light source light may have one or more wavelengths in the blue wavelength range, the first luminescent material light may have one or more wavelengths in the red wavelength range, and the second luminescent material light may have one or wavelengths in the yellow-green wavelength range. Hence, the device light in embodiments may have three or more centroid wavelengths. This may approximate desirable white light better than two or more centroid wavelengths. The phrase “one or wavelengths in the yellow-green wavelength range” may indicate intensity at one or more wavelengths in the green wavelength range and/or intensity at one or more wavelengths in the yellow wavelength range.

In yet further embodiments, the luminescent element may comprise a third luminescent material, different from the first luminescent material and different from the second luminescent material. The third luminescent material may be configured to convert at least part of the light source light into third luminescent material light. The device light may thus comprise the light source light, the first luminescent material light, the second luminescent material light, and the third luminescent material light. The third luminescent material light may have one or more wavelengths in the orange wavelength range. In embodiments, the third luminescent material may comprise (Ba,Sr,Ca)AlSiN₃:Eu, which is further described below.

In embodiments, the luminescent element may comprise 0.3-20 wt % of the third luminescent material, as has been described similarly for the first luminescent material (and second luminescent material) above. This may especially apply when the third luminescent material comprises (Ba,Sr,Ca)AlSiN₃:Eu.

Especially, in embodiments, the light source light may have one or more wavelengths in the blue wavelength range, the first luminescent material light may have one or more wavelengths in the red wavelength range, the second luminescent material light may have one or wavelengths in the yellow-green wavelength range, and the third luminescent material light may have one or more wavelengths in the orange wavelength range. Hence, the device light in embodiments may have four (or more) centroid wavelengths (especially in embodiments in each of the indicated wavelengths a respective centroid wavelength). This may approximate desirable white light better than three or more centroid wavelengths.

Here below, some general aspects in relation to luminescent materials are described, followed with some examples of luminescent materials that may be used as second luminescent, or third luminescent material (or even further luminescent materials).

The term “luminescent material” especially refers to a material that can convert first radiation, especially one or more of UV radiation and blue radiation, into second radiation. In general, the first radiation and second radiation have different spectral power distributions. Hence, instead of the term “luminescent material”, also the terms “luminescent converter” or “converter” may be applied. In general, the second radiation has a spectral power distribution at larger wavelengths than the first radiation, which is the case in the so-called down-conversion. In specific embodiments, however the second radiation has a spectral power distribution with intensity at smaller wavelengths than the first radiation, which is the case in the so-called up-conversion.

In embodiments, the “luminescent material” may especially refer to a material that can convert radiation into e.g. visible and/or infrared light. For instance, in embodiments the luminescent material may be able to convert one or more of UV radiation and blue radiation, into visible light. The luminescent material may in specific embodiments also convert radiation into infrared radiation (IR). Hence, upon excitation with radiation, the luminescent material emits radiation. In general, the luminescent material will be a down converter, i.e. radiation of a smaller wavelength is converted into radiation with a larger wavelength (λₑₓ<λₑₘ), though in specific embodiments the luminescent material may comprise up-converter luminescent material, i.e. radiation of a larger wavelength is converted into radiation with a smaller wavelength (λₑₓ>λₑₘ).

In embodiments, the term “luminescence” may refer to phosphorescence. In embodiments, the term “luminescence” may also refer to fluorescence. Instead of the term “luminescence”, also the term “emission” may be applied. Hence, the terms “first radiation” and “second radiation” may refer to excitation radiation and emission (radiation), respectively. Likewise, the term “luminescent material” may in embodiments refer to phosphorescence and/or fluorescence.

The term “luminescent material” may also refer to a plurality of different luminescent materials. Examples of possible luminescent materials are indicated below. Hence, the term “luminescent material” may in specific embodiments also refer to a luminescent material composition. Instead of the term “luminescent material” also the term “phosphor”. These terms are known to the person skilled in the art.

In embodiments, luminescent materials are selected from garnets and nitrides, especially doped with trivalent cerium or divalent europium, respectively. The term “nitride” may also refer to oxynitride or nitridosilicate, etc. Alternatively or additionally, the luminescent material(s) may be selected from silicates, especially doped with divalent europium.

In specific embodiments the luminescent material comprises a luminescent material of the type A₃B₅O₁₂:Ce, wherein A in embodiments comprises one or more of Y, La, Gd, Tb and Lu, especially (at least) one or more of Y, Gd, Tb and Lu, and wherein B in embodiments comprises one or more of Al, Ga, In and Sc. Especially, A may comprise one or more of Y, Gd and Lu, such as especially one or more of Y and Lu. Especially, B may comprise one or more of Al and Ga, more especially at least Al, such as essentially entirely Al. Hence, especially suitable luminescent materials are cerium comprising garnet materials. Embodiments of garnets especially include A₃B₅O₁₂ garnets, wherein A comprises at least yttrium or lutetium and wherein B comprises at least aluminum. Such garnets may be doped with cerium (Ce), with praseodymium (Pr) or a combination of cerium and praseodymium; especially however with Ce. Especially, B may comprise aluminum (Al); however, in addition to aluminum, B may also partly comprise gallium (Ga) and/or scandium (Sc) and/or indium (In), especially up to about 20% of B, more especially up to about 10% of B (i.e. the B ions essentially consist of 90 or more mole % of Al and 10 or less mole % of one or more of Ga, Sc, and In); B may especially comprise up to about 10% gallium. In another variant, B and O may at least partly be replaced by Si and N. The element A may especially be selected from the group consisting of yttrium (Y), gadolinium (Gd), terbium (Tb) and lutetium (Lu). Further, Gd and/or Tb are especially only present up to an amount of about 20% of A. In a specific embodiment, the garnet luminescent material comprises (Y₁₋ₓLuₓ)₃B₅O₁₂:Ce, wherein x is equal to or larger than 0 and equal to or smaller than 1. The term “:Ce”, indicates that part of the metal ions (i.e. in the garnets: part of the “A” ions) in the luminescent material is replaced by Ce. For instance, in the case of (Y₁₋ₓLuₓ)₃Al₅O₁₂:Ce, part of Y and/or Lu is replaced by Ce. This is known to the person skilled in the art. Ce will replace A in general for not more than 10%; in general, the Ce concentration will be in the range of 0.1 to 4%, especially 0.1 to 2% (relative to A). Assuming 1% Ce and 10% Y, the full correct formula could be (Y_{0.1}Lu_{0.89}Ce_{0.01})₃Al₅O₁₂. Ce in garnets is substantially or only in the trivalent state, as is known to the person skilled in the art.

In embodiments, the luminescent material (thus) comprises A₃B₅O₁₂ wherein in specific embodiments at maximum 10% of B-O may be replaced by Si—N.

In specific embodiments the luminescent material comprises (Yₓ₁₋ₓ₂₋ₓ₃A′ₓ₂Ceₓ₃)₃(Al_{y1-y2}B′_{y2})₅O₁₂, wherein x1+x2+x3=1, wherein x3>0, wherein 0<x2+x3≤0.2, wherein y1+y2=1, wherein 0≤y2≤0.2, wherein A′ comprises one or more elements selected from the group consisting of lanthanides, and wherein B′ comprises one or more elements selected from the group consisting of Ga, In and Sc. In embodiments, x3 is selected from the range of 0.001-0.1. In the present invention, especially x1>0, such as >0.2, like at least 0.8. Garnets with Y may provide suitable spectral power distributions.

In specific embodiments at maximum 10% of B-O may be replaced by Si—N. Here, B in B-O refers to one or more of Al, Ga, In and Sc (and O refers to oxygen); in specific embodiments B-O may refer to Al—O. As indicated above, in specific embodiments x3 may be selected from the range of 0.001-0.04. Especially, such luminescent materials may have a suitable spectral distribution (see however below), have a relatively high efficiency, have a relatively high thermal stability, and allow a high CRI (optionally in combination with (the) light of other sources of light as described herein). Hence, in specific embodiments A may be selected from the group consisting of Lu and Gd. Alternatively or additionally, B may comprise Ga. Hence, in embodiments the luminescent material comprises (Yₓ₁₋ₓ₂₋ₓ₃(Lu,Gd)ₓ₂Ceₓ₃)₃(Al_{y1-y2}Ga_{y2})₅O₁₂, wherein Lu and/or Gd may be available. Even more especially, x3 is selected from the range of 0.001-0.1, wherein 0<x2+x3≤0.1, and wherein 0≤y2≤0.1. Further, in specific embodiments, at maximum 1% of B-O may be replaced by Si—N. Here, the percentage refers to moles (as known in the art); see e.g. also EP3149108. In yet further specific embodiments, the luminescent material comprises (Yₓ₁₋ₓ₃Ceₓ₃)₃Al₅O₁₂, wherein x1+x3=1, and wherein 0<x3≤0.2, such as 0.001-0.1.

In specific embodiments, the light generating device may only include luminescent materials selected from the type of cerium comprising garnets. Hence, in specific embodiments the light generating device comprises luminescent material, wherein at least 85 weight %, even more especially at least about 90 wt. %, such as yet even more especially at least about 95 weight % of the luminescent material comprises (Yₓ₁₋ₓ₂₋ₓ₃A′ₓ₂Ceₓ₃)₃(Al_{y1-y2}B′_{y2})₅O₁₂. Here, wherein A′ comprises one or more elements selected from the group consisting of lanthanides, and wherein B′ comprises one or more elements selected from the group consisting of Ga, In and Sc, wherein x1+x2+x3=1, wherein x3>0, wherein 0<x2+x3≤0.2, wherein y1+y2=1, wherein 0≤y2≤0.2. Especially, x3 is selected from the range of 0.001-0.1. Note that in embodiments x2=0. Alternatively or additionally, in embodiments y2=0.

In specific embodiments, A may especially comprise at least Y, and B may especially comprise at least Al.

Alternatively or additionally, wherein the luminescent material may comprise a luminescent material of the type A₃Si₆N₁₁:Ce³⁺, wherein A comprises one or more of Y, La, Gd, Tb and Lu, such as in embodiments one or more of La and Y.

In embodiments, the luminescent material may alternatively or additionally comprise one or more of MS:Eu²⁺ and/or M₂Si₅N₈:Eu²⁺ and/or MAlSiN₃:Eu²⁺ and/or Ca₂AlSi₃O₂N₅:Eu²⁺, etc., wherein M comprises one or more of Ba, Sr and Ca, especially in embodiments at least Sr. Hence, in embodiments, the luminescent may comprise one or more materials selected from the group consisting of (Ba,Sr,Ca)S:Eu, (Ba,Sr,Ca)AlSiN₃:Eu and (Ba,Sr,Ca)₂Si₅N₈:Eu. In these compounds, europium (Eu) is substantially or only divalent, and replaces one or more of the indicated divalent cations. In general, Eu will not be present in amounts larger than 10% of the cation; its presence will especially be in the range of about 0.5 to 10%, more especially in the range of about 0.5 to 5% relative to the cation(s) it replaces. The term “:Eu”, indicates that part of the metal ions is replaced by Eu (in these examples by Eu²⁺). For instance, assuming 2% Eu in CaAlSiN₃:Eu, the correct formula could be (Ca_{0.98}Eu_{0.02})AlSiN₃. Divalent europium will in general replace divalent cations, such as the above divalent alkaline earth cations, especially Ca, Sr or Ba. The material (Ba,Sr,Ca)S:Eu can also be indicated as MS:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca). Further, the material (Ba,Sr,Ca)₂Si₅N₈:Eu can also be indicated as M₂Si₅N₈:Eu, wherein M is one or more elements selected from the group consisting of barium (Ba), strontium (Sr) and calcium (Ca); especially, M comprises in this compound Sr and/or Ba. In a further specific embodiment, M consists of Sr and/or Ba (not taking into account the presence of Eu), especially 50 to 100%, more especially 50 to 90% Ba and 50 to 0%, especially 50 to 10% Sr, such as Ba_{1.5}Sr_{0.5}Si₅N₈:Eu (i.e. 75% Ba; 25% Sr). Here, Eu is introduced and replaces at least part of M, i.e. one or more of Ba, Sr, and Ca). Likewise, the material (Ba,Sr,Ca)AlSiN₃:Eu can also be indicated as MAlSiN₃:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca). Eu in the above indicated luminescent materials is substantially or only in the divalent state, as is known to the person skilled in the art.

In embodiments, a red luminescent material may comprise one or more materials selected from the group consisting of (Ba,Sr,Ca)S:Eu, (Ba,Sr,Ca)AlSiN₃:Eu and (Ba,Sr,Ca)₂Si₅N₈:Eu. In these compounds, europium (Eu) is substantially or only divalent, and replaces one or more of the indicated divalent cations. In general, Eu will not be present in amounts larger than 10% of the cation; its presence will especially be in the range of about 0.5 to 10%, more especially in the range of about 0.5 to 5% relative to the cation(s) it replaces. The term “:Eu”, indicates that part of the metal ions is replaced by Eu (in these examples by Eu²⁺). For instance, assuming 2% Eu in CaAlSiN₃:Eu, the correct formula could be (Ca_{0.98}Eu_{0.02})AlSiN₃. Divalent europium will in general replace divalent cations, such as the above divalent alkaline earth cations, especially Ca, Sr or Ba.

The material (Ba,Sr,Ca)S:Eu can also be indicated as MS:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca).

Further, the material (Ba,Sr,Ca)₂Si₅N₈:Eu can also be indicated as M₂Si₅N₈:Eu, wherein M is one or more elements selected from the group consisting of barium (Ba), strontium (Sr) and calcium (Ca); especially, M comprises in this compound Sr and/or Ba. In a further specific embodiment, M consists of Sr and/or Ba (not taking into account the presence of Eu), especially 50 to 100%, more especially 50 to 90% Ba and 50 to 0%, especially 50 to 10% Sr, such as Ba_{1.5}Sr_{0.5}Si₅N₈:Eu (i.e. 75% Ba; 25% Sr). Here, Eu is introduced and replaces at least part of M, i.e. one or more of Ba, Sr, and Ca).

Likewise, the material (Ba,Sr,Ca)AlSiN₃:Eu can also be indicated as MAlSiN₃:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca).

Eu in the above indicated luminescent materials is substantially or only in the divalent state, as is known to the person skilled in the art.

Blue luminescent materials may comprise YSO (Y₂SiO₅:Ce³⁺), or similar compounds, or BAM (BaMgAl₁₀O₁₇:Eu²⁺), or similar compounds.

The term “luminescent material” herein especially relates to inorganic luminescent materials.

Alternatively or additionally, also other luminescent materials may be applied. For instance quantum dots and/or organic dyes may be applied and may optionally be embedded in transmissive matrices like e.g. polymers, like PMMA, or polysiloxanes, etc. etc.

Quantum dots are small crystals of semiconducting material generally having a width or diameter of only a few nanometers. When excited by incident light, a quantum dot emits light of a color determined by the size and material of the crystal. Light of a particular color can therefore be produced by adapting the size of the dots. Most known quantum dots with emission in the visible range are based on cadmium selenide (CdSe) with a shell such as cadmium sulfide (CdS) and zinc sulfide (ZnS). Cadmium free quantum dots such as indium phosphide (InP), and copper indium sulfide (CuInS₂) and/or silver indium sulfide (AgInS₂) can also be used. Quantum dots show very narrow emission band and thus they show saturated colors. Furthermore the emission color can easily be tuned by adapting the size of the quantum dots. Any type of quantum dot known in the art may be used in the present invention. However, it may be preferred for reasons of environmental safety and concern to use cadmium-free quantum dots or at least quantum dots having a very low cadmium content.

Instead of quantum dots or in addition to quantum dots, also other quantum confinement structures may be used. The term “quantum confinement structures” should, in the context of the present application, be understood as e.g. quantum wells, quantum dots, quantum rods, tripods, tetrapods, or nano-wires, etcetera.

Organic phosphors can be used as well. Examples of suitable organic phosphor materials are organic luminescent materials based on perylene derivatives, for example compounds sold under the name Lumogen® by BASF. Examples of suitable compounds include, but are not limited to, Lumogen® Red F305, Lumogen® Orange F240, Lumogen® Yellow F083, and Lumogen® F170.

Different luminescent materials may have different spectral power distributions of the respective luminescent material light. Alternatively or additionally, such different luminescent materials may especially have different color points (or dominant wavelengths).

As indicated above, other luminescent materials may also be possible. Hence, in specific embodiments the luminescent material is selected from the group of divalent europium containing nitrides, divalent europium containing oxynitrides, divalent europium containing silicates, cerium comprising garnets, and quantum structures. Quantum structures may e.g. comprise quantum dots or quantum rods (or other quantum type particles) (see above). Quantum structures may also comprise quantum wells. Quantum structures may also comprise photonic crystals.

Some further embodiments are described below.

Especially, the device light in embodiments may be white light having a color rendering index value of at least 70, such as at least 80. Further, in embodiments the device light may be white light having an R9 value of at least about 0. In specific embodiments, the device light in embodiments may be white light having a color rendering index value of at least 85 and/or an R9 value of at least 0, more especially at least a CRI of at least 85, or even at least 90.

The term “white light”, and similar terms, herein, is known to the person skilled in the art. It may especially relate to light having a correlated color temperature (CCT) between about 1800 K and 20000 K, such as between 2000 and 20000 K, especially 2700-20000 K, for general lighting especially in the range of about 2000-7000 K, such as in the range of 2700 K and 6500 K. In embodiments, e.g. for backlighting purposes, or for other purposes, the correlated color temperature (CCT) may especially be in the range of about 7000 K and 20000 K. Yet further, in embodiments the correlated color temperature (CCT) is especially within about 15 SDCM (standard deviation of color matching) from the BBL (black body locus), especially within about 10 SDCM from the BBL, even more especially within about 5 SDCM from the BBL. In specific embodiments, the correlated color temperature (CCT) may be selected from the range of 6000-12000 K, like selected from the range of 7000-12000 K, like at least 8000 K. Yet further, in embodiments the correlated color temperature (CCT) may be selected from the range of 6000-12000 K, like selected from the range of 7000-12000 K, in combination with a CRI of at least 70.

In embodiments, wherein the device light is white light, the light luminescent element may at least comprise the first luminescent material and the second luminescent material, more especially also at least the third luminescent material.

In embodiments, the first luminescent material, the second luminescent material, and the third luminescent material may be distributed as an even particulate concentration across the entire luminescent element.

In other embodiments, the first luminescent material, second luminescent material, and third luminescent material may be distributed in (respective) layers within the luminescent element. Especially, in such embodiments the first luminescent material may be comprised by the first layer encountered by the device light.

In embodiments, the first luminescent material, second luminescent material, and third luminescent material may be distributed in concentration gradients ranging from a low to a high weight percentage (or vice versa) within the luminescent element. These concentration gradients may be partially overlapping, i.e. the along a line a weight percentage of one of the luminescent materials may increase and a weight percentage of another one of the decreases. In other embodiments, the gradient concentrations may be non-overlapping. In embodiments, there is a concentration gradient in the luminescent element, such that a local weight percentage of the first luminescent material closer to the wire bonding is lower than further away from the wire bonding.

In embodiments, the light source light may have a centroid wavelength selected from the range of 440-480 nm. The first luminescent material light may have a centroid wavelength selected from the range of 620-680 nm. The second luminescent material light may have a centroid wavelength selected from the range of 530-580 nm. The third luminescent material light may have a centroid wavelength selected from the range of 580-620 nm. The centroid wavelengths may mutually differ with at least 10 nm, such as differences selected from the range of 15-300 nm, such as 15-250 nm, like at least 20 nm.

The term “centroid wavelength”, also indicated as λc, is known in the art, and refers to the wavelength value where half of the light energy is at shorter and half the energy is at longer wavelengths; the value is stated in nanometers (nm). It is the wavelength that divides the integral of a spectral power distribution into two equal parts as expressed by the formula λc=Σλ*I(λ)/(ΣI(λ), where the summation is over the wavelength range of interest, and I(λ) is the spectral energy density (i.e. the integration of the product of the wavelength and the intensity over the emission band normalized to the integrated intensity). The centroid wavelength may e.g. be determined at operation conditions. The phrase “having one or more wavelengths in a specific wavelength range”, and similar phrases (such as “having one or more wavelengths in the blue wavelength range”), does not necessarily include that also intensity at wavelengths external from the specific wavelength range may be found. For instance, a green/yellow luminescent material (see also below) may in embodiments e.g. also have intensity in the orange wavelength range. Especially, however, this indication may indicate that the light having these one or more wavelengths in the specific wavelength range may also have the color related to that wavelength range. Hence, e.g. a centroid wavelength of the light one or more wavelengths in the specific wavelength range may be in that specific wavelength range.

It is herein not excluded that further luminescent materials may be available.

In embodiments, the first luminescent material may have a CIE 1931 color point of x=0.693+/−a1 and y=0.307+/−b1, wherein a1 and b1 are both individually selected from the range of 0-0.05.

In embodiments, the second luminescent material may have a CIE color point of x=0.366+/−a2 and y=0.577+/−b2, wherein a2 and b2 are both individually selected from the range of 0-0.1.

In embodiments, the third luminescent material may have a CIE color point of x=0.654+/−a3 and y=0.345+/−b3, wherein a3 and b3 are both individually selected from the range of 0-0.1.

In embodiments, the light generating device may comprise a reflective layer. Especially, the reflective layer may be positioned covering at least part of the support. Optionally, the reflective layer may cover part of a conductive element (or instance on top of a metal leadframe). Such a reflective layer may allow for light source light escaping in the direction of the support to be reflected. This reflected device light may then be comprised by the device light. Hence, the light generating device may generate light more efficiently. The term “reflective layer” may in specific embodiments also refer to a plurality of reflective layers, which may be configured adjacent or remote from each other.

Such reflective layers may especially be a mirror element. The mirror may be made of a metal or a metal alloy. Especially, like the wire bonding, the mirror element may have a low concentration of Ag so as to prevent degradation. In embodiments, the mirror element may be a reflective layer on at least part of the support. In embodiments, the mirror element may in embodiments comprise an alloy comprising 1-60 wt % Ag. Especially, the mirror element may comprise an alloy comprising 1-40 wt % Ag. In other embodiments, there may be little risk on blackening reaching the mirror element (e.g. using a KSF-free zone covering the mirror element). In such embodiments, mirror element may have a high(er) concentration of Ag of (even) up to 100%.

In embodiments, there is a concentration gradient in the luminescent element, such that a local weight percentage of the first luminescent material closer to the mirror element is lower than further away from the mirror element. For instance, a first part of the luminescent element may substantially not comprise the first luminescent material, and a second part of the luminescent element may comprise the first luminescent material. The first and the second part may be layers comprised by the luminescent element.

Alternatively or additionally, on the reflective layer a (thin) light transmissive coating may be applied, like a silicone coating or other type of light transmissive coating.

Yet, alternatively or additionally, the first luminescent material may comprise a coating, i.e. first luminescent material particles having a coating surrounding the particle. Such coatings are known in the art and e.g. described in e.g. EP3950879 or WO2013/121355, which are herein incorporated by reference.

Hence, in embodiments the mirror element may have concentration of Ag selected from the range of 1-100 wt %, such as selected from e.g. the range of 1-40 wt %, when the mirror and first luminescent material may be in physical contact with each other, or at least 40 wt %, more especially at least 80 wt %, or even 100 wt %, wherein the first luminescent material is not in direct contact with the mirror element.

Applications of the light generating device as described above may be in the form of a lighting device. These may be selected from the group of a lamp, a luminaire, a projector device, a disinfection device, a photochemical reactor, and an optical wireless communication device, comprising the light generating device as described above. In such applications, the light generating device may be part of a light generating system, configured to provide device light as system light. The light generating system may be part of or may be applied in e.g. office lighting systems, household application systems, shop lighting systems, home lighting systems, accent lighting systems, spot lighting systems, theater lighting systems, fiber-optics application systems, projection systems, self-lit display systems, pixelated display systems, segmented display systems, warning sign systems, medical lighting application systems, indicator sign systems, decorative lighting systems, portable systems, automotive applications, (outdoor) road lighting systems, urban lighting systems, green house lighting systems, horticulture lighting, digital projection, or LCD backlighting. The light generating system (or luminaire) may be part of or may be applied in e.g. optical communication systems or disinfection systems.

The system, or apparatus, or device may execute an action in a “mode” or “operation mode” or “mode of operation” or “operational mode”. The term “operational mode may also be indicated as “controlling mode”. Likewise, in a method an action or stage, or step may be executed in a “mode” or “operation mode” or “mode of operation” or “operational mode”. This does not exclude that the system, or apparatus, or device may also be adapted for providing another controlling mode, or a plurality of other controlling modes. Likewise, this may not exclude that before executing the mode and/or after executing the mode one or more other modes may be executed.

In yet a further aspect, the invention also provides a lamp or a luminaire comprising the light generating system as defined herein. The luminaire may further comprise a housing, optical elements, louvres, etc. etc . . . The lamp or luminaire may further comprise a housing enclosing the light generating system. The lamp or luminaire may comprise a light window in the housing or a housing opening, through which the system light may escape from the housing. In yet a further aspect, the invention also provides a projection device comprising the light generating system as defined herein. Especially, a projection device or “projector” or “image projector” may be an optical device that projects an image (or moving images) onto a surface, such as e.g. a projection screen. The projection device may include one or more light generating systems such as described herein. Hence, in an aspect the invention also provides a light generating device selected from the group of a lamp, a luminaire, a projector device, a disinfection device, and an optical wireless communication device, comprising the light generating system as defined herein. The light generating device may comprise a housing or a carrier, configured to house or support, one or more elements of the light generating system. For instance, in embodiments the light generating device may comprise a housing or a carrier, configured to house or support one or more of the light source.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1A-B schematically depict an embodiment of the light generating device.

FIG. 2A-B schematically depict other embodiments of the light generating device.

FIG. 3 schematically depicts embodiments of a chip-on-board light generating device.

FIG. 4 shows a graph of the device light wavelength and intensity of embodiments.

FIG. 5 schematically depicts some applications of embodiments of the light generating device.

The schematic drawings are not necessarily to scale.

### DETAILED DESCRIPTION OF THE EMBODIMENTS

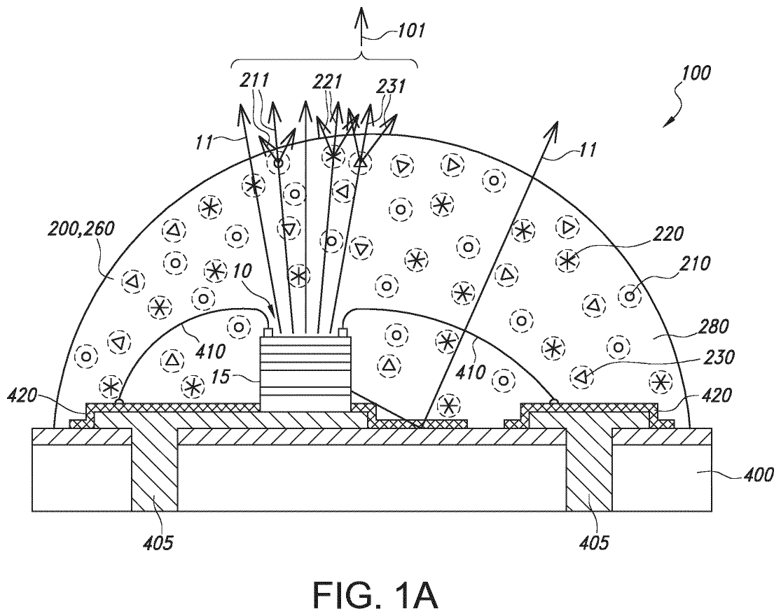

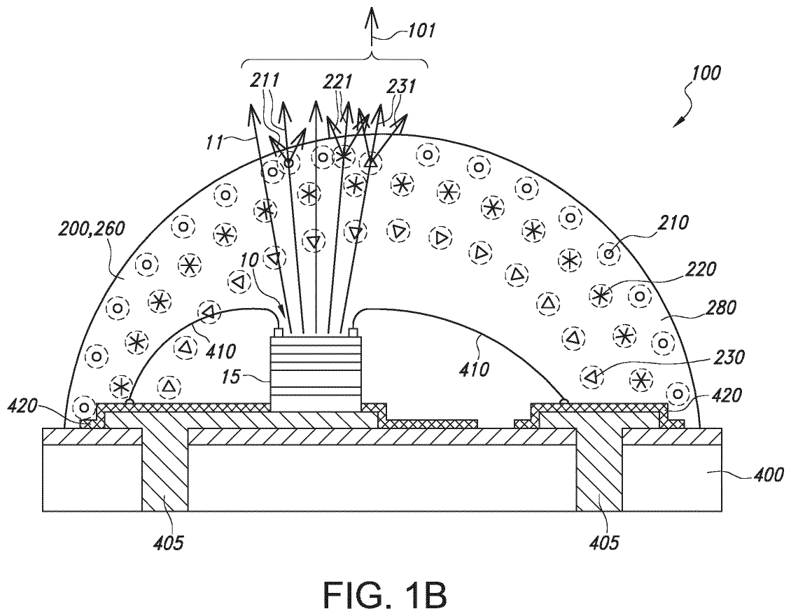

FIG. 1A-B schematically depicts a light generating device 100 configured to provide device light 101, wherein the light generating device 100 comprises: a light source 10 configured to provide light source light 11, wherein the light source 10 comprises a solid state light source 15. The light generating device 100 may further comprise a support 400 comprising an electrical conductor 405; wherein the support 400 is configured to support the light source 10. The light generating device 100 may yet further comprise a wire bonding 410 configured to provide an electrical connection between the solid state light source 15 and the electrical conductor 405, wherein the wire bonding 410 comprises 1-40 wt % Ag. The light generating device may further yet comprises a luminescent element 200 configured in contact with the solid state light source 15 and the wire bonding 410; wherein the luminescent element 200 comprises a first luminescent material 210, configured to convert at least part of the light source light 11 into first luminescent material light 211, wherein the first luminescent material 210 comprises M′ₓM₂₋₂ₓAX₆ doped with tetravalent manganese, wherein M′ comprises an alkaline earth cation, wherein M comprises an (alkaline) cation, and x is in the range of 0-1, wherein A comprises a tetravalent cation, in specific embodiments at least comprising silicon, wherein X comprises a monovalent anion, at least comprising fluorine. In embodiments, the device light 101 may comprise the first luminescent material light 211.

FIGS. 1A-B further schematically depict embodiments of the light generating device 100. The wire bonding 410 may comprise an alloy that comprises at least 60 wt % Au and 20-40 wt % Ag. The luminescent element 200 may comprise 5-60 wt % of the first luminescent material 210, wherein M′ₓM₂₋₂ₓAX₆ comprises K₂SiF₆. 4. The luminescent element 200 may comprise a light transmissive dome 260 comprising the first luminescent material 210. The light transmissive dome 260 may comprise an encapsulation material 280 comprising e.g. silicone or PMMA or epoxy. The light source 10 and the first luminescent material 210 may be configured such that part of the light source light 11 escapes from the light generating device 100 comprised by the device light 101 without being converted by the first luminescent material 210. The light generating device 100 may in embodiments be configured to generate device light 101 comprising the light source light 11 and the first luminescent material light 211. The light source light 11 may have one or more wavelengths in the blue wavelength range. The first luminescent material light 211 has one or more wavelengths in the red wavelength range. The support 400 may comprise a reflective layer 420, e.g. comprising 1-60 wt % Ag, such as 1-40 wt % Ag.

FIG. 1A-B schematically depict further embodiments wherein the luminescent element 200 comprises a second luminescent material 220, different from the first luminescent material 210, configured to convert at least part of the light source light 11 into second luminescent material light 221. The device light 101 may comprise the first luminescent material light 211 and the second luminescent material light 221. The luminescent element 200 may comprise 5-60 wt % of the second luminescent material 220. The second luminescent material light 221 may have one or more wavelengths in the green-yellow wavelength range. The second luminescent material 220 may comprise a luminescent material of the type A₃B₅O₁₂:Ce, wherein A comprises one or more of Y, La, Gd, Tb and Lu, and wherein B comprises one or more of Al, Ga, In and Sc. The light source 10, the first luminescent material 210, and the second luminescent material 220 may be configured such that part of the light source light 11 escapes from the light generating device 100 comprised by the device light 101 without being converted by the first luminescent material 210 or the second luminescent material 220. The light generating device 100 may be configured to generate device light 101 comprising the light source light 11, the first luminescent material light 211, and the second luminescent material light 221.

FIG. 1A-B schematically depicts yet further embodiments wherein the luminescent element 200 may comprise a third luminescent material 230, different from the first luminescent material 210 and different from the second luminescent material 220. The third luminescent material 230 is configured to convert at least part of the light source light 11 into third luminescent material light 231. The device light 101 may comprise the light source light 11, the first luminescent material light 211, the second luminescent material light 221, and the third luminescent material light 231. The third luminescent material light 231 may have one or more wavelengths in the orange wavelength range. The device light 101 may be white light having a color rendering index value of at least 80. The luminescent element 200 comprises 0.3-20 wt % of the third luminescent material 230.

FIG. 1A schematically depicts embodiments wherein the first luminescent material 210, second luminescent material 220, and third luminescent material 230 may be randomly distributed across the luminescent element 200.

FIG. 1B schematically depicts embodiments wherein the first luminescent material 210, second luminescent material 220, and third luminescent material 230 may be distributed in layers within the luminescent element 200. The first luminescent material 210, second luminescent material 220, and third luminescent material 230 may be distributed in concentration gradients within the luminescent element 200.

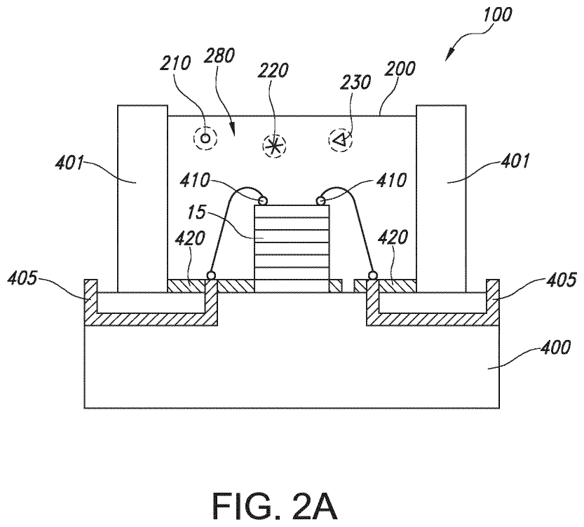

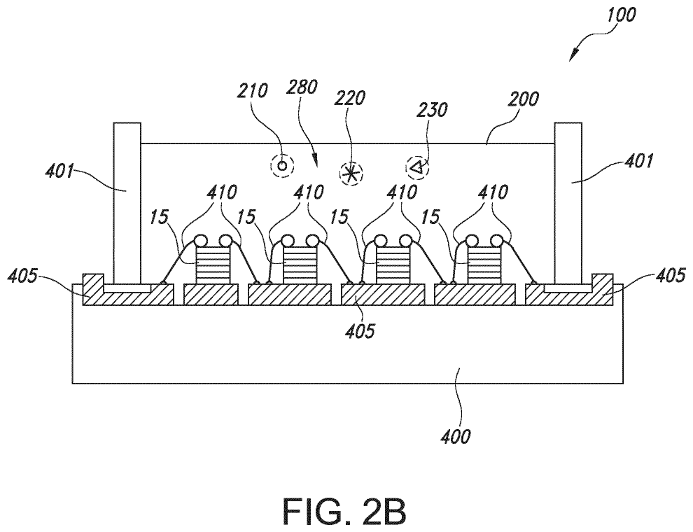

FIG. 2A-B schematically depicts embodiments of the light generating device 100 where the luminescent element 200 may be contained by at least one or more (support) dams 401. FIG. 2B schematically depicts an embodiment of a chip-on-board light generating device 1400 with a plurality of light sources 10 wherein the luminescent element 200 is contained by support dams 401.

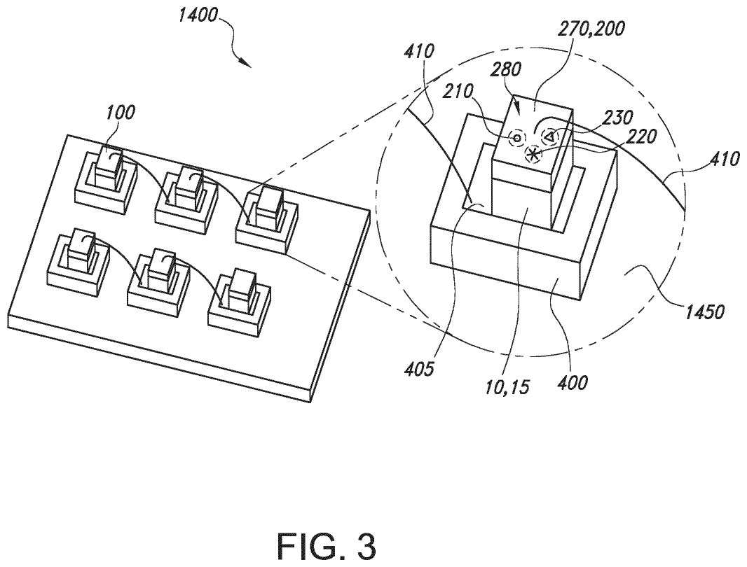

FIG. 3 schematically depicts embodiments of the light generating device 100 comprising a chip-on-board light generating device 1400. The chip-on-board light generating device 1400 may comprise the light source 10. The light generating device 100 further comprises a luminescent layer 270 comprising the luminescent material 200 configured downstream of the chip-on-board light generating device 1400 (and especially configured to convert the light source light 11 of a plurality of light sources 10).

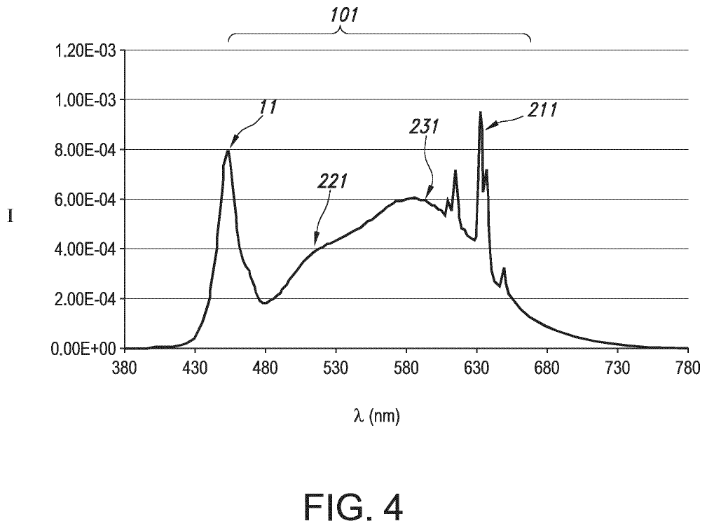

FIG. 4 shows a graph of the device light wavelength and intensity of embodiments. The light source light 11 has a centroid wavelength selected from the range of 440-480 nm. The first luminescent material light 211 has a centroid wavelength selected from the range of 620-680 nm. The second luminescent material light 221 has a centroid wavelength selected from the range of 530-580 nm. The third luminescent material light 231 has a centroid wavelength selected from the range of 580-620 nm. The centroid wavelengths mutually differ with at least 10 nm.

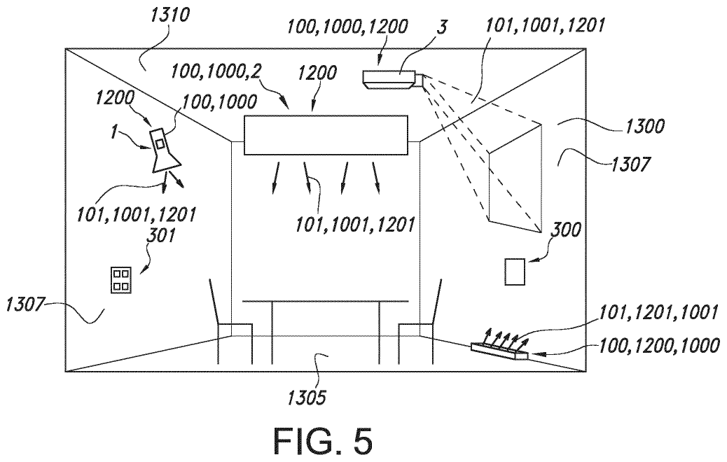

FIG. 5 schematically depicts some applications of embodiments of the light generating device 100 as part of a light generating system 1000 configured to provide device light 101 as system light 1001. A lighting device 1200 selected from the group of a lamp 1, a luminaire 2, a projector device 3, a disinfection device, a photochemical reactor, and an optical wireless communication device, comprising the light generating device 100 as described above. The light generating system 1000 may be placed in a space 1300 comprising a floor 1305, walls 1307, and a ceiling 1310. Reference 301 indicates a user interface which may be functionally coupled with the control system 300 comprised by or functionally coupled to the light generating system 1000 comprising the light generating device 100. FIG. 4 also schematically depicts an embodiment of lamp 1 comprising the light generating system 1000. Reference 3 indicates a projector device or projector system, which may be used to project images, such as at a wall, which may also comprise the light generating system 1000.

The term “plurality” refers to two or more.

The terms “substantially” or “essentially” herein, and similar terms, will be understood by the person skilled in the art. The terms “substantially” or “essentially” may also include embodiments with “entirely”, “completely”, “all”, etc. Hence, in embodiments the adjective substantially or essentially may also be removed. Where applicable, the term “substantially” or the term “essentially” may also relate to 90% or higher, such as 95% or higher, especially 99% or higher, even more especially 99.5% or higher, including 100%.

The term “comprise” includes also embodiments wherein the term “comprises” means “consists of”.

The term “and/or” especially relates to one or more of the items mentioned before and after “and/or”. For instance, a phrase “item 1 and/or item 2” and similar phrases may relate to one or more of item 1 and item 2. The term “comprising” may in an embodiment refer to “consisting of” but may in another embodiment also refer to “containing at least the defined species and optionally one or more other species”.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

The devices, apparatus, or systems may herein amongst others be described during operation. As will be clear to the person skilled in the art, the invention is not limited to methods of operation, or devices, apparatus, or systems in operation.

It should be noted that the above-mentioned embodiments illustrate rather than limit the invention, and that those skilled in the art will be able to design many alternative embodiments without departing from the scope of the appended claims.

In the claims, any reference signs placed between parentheses shall not be construed as limiting the claim.

Use of the verb “to comprise” and its conjugations does not exclude the presence of elements or steps other than those stated in a claim. Unless the context clearly requires otherwise, throughout the description and the claims, the words “comprise”, “comprising”, and the like are to be construed in an inclusive sense as opposed to an exclusive or exhaustive sense; that is to say, in the sense of “including, but not limited to”.

The article “a” or “an” preceding an element does not exclude the presence of a plurality of such elements.

The invention may be implemented by means of hardware comprising several distinct elements, and by means of a suitably programmed computer. In a device claim, or an apparatus claim, or a system claim, enumerating several means, several of these means may be embodied by one and the same item of hardware. The mere fact that certain measures are recited in mutually different dependent claims does not indicate that a combination of these measures cannot be used to advantage. In yet a further aspect, the invention (thus) provides a software product, which, when running on a computer is capable of bringing about (one or more embodiments of) the method as described herein.

The invention also provides a control system that may control the device, apparatus, or system, or that may execute the herein described method or process. Yet further, the invention also provides a computer program product, when running on a computer which is functionally coupled to or comprised by the device, apparatus, or system, controls one or more controllable elements of such device, apparatus, or system.

The invention further applies to a device, apparatus, or system comprising one or more of the characterizing features described in the description and/or shown in the attached drawings. The invention further pertains to a method or process comprising one or more of the characterizing features described in the description and/or shown in the attached drawings.

The various aspects discussed in this patent can be combined in order to provide additional advantages. Further, the person skilled in the art will understand that embodiments can be combined, and that also more than two embodiments can be combined. Furthermore, some of the features can form the basis for one or more divisional applications.

1. A light generating device configured to provide device light, wherein the light generating device comprises:
a light source configured to provide light source light, wherein the light source comprises a solid state light source;
a support comprising an electrical conductor; wherein the support is configured to support the light source;
a wire bonding configured to provide an electrical connection between the solid state light source and the electrical conductor, wherein the wire bonding comprises a metal alloy material;
a luminescent element configured in contact with the solid state light source and the wire bonding; wherein the luminescent element comprises a particulate first luminescent material, configured to convert at least part of the light source light into first luminescent material light, wherein the particulate first luminescent material comprises M₂AX₆ doped with tetravalent manganese, wherein M comprises an alkaline cation, wherein A comprises a tetravalent cation, wherein X comprises a monovalent anion, at least comprising fluorine, and wherein the particulate first luminescent material has a d50 value selected from the range of 5-50 μm;
wherein the device light comprises the first luminescent material light;
wherein the metal alloy material comprises 5-40 wt. % Ag and the rest of the metal alloy material comprises 60-95 wt. % Au; the metal alloy material optionally further comprises other metal materials up to 5 wt. % of the metal alloy material;
wherein the luminescent element comprises 5-60 wt. % of M₂AX₆ doped with tetravalent manganese.

2. The light generating device according to claim 1, wherein A comprises silicon.

3. The light generating device according to claim 1, wherein M₂AX₆ comprises K₂SiF₆.

4. The light generating device according to claim 1, wherein the luminescent element comprises a light transmissive dome comprising the particulate first luminescent material; wherein the light transmissive dome comprises an encapsulation material wherein the particulate first luminescent material is embedded, wherein the encapsulation material comprises one or more of a silicone, epoxy, polycarbonate, and PMMA.

5. The light generating device according to claim 1, comprising a chip-on-board light generating device, wherein the chip-on-board light generating device comprises the light source; wherein the light generating device further comprises a luminescent layer comprising the luminescent element.

6. The light generating device according to claim 1, wherein the light generating device is configured to generate device light comprising the light source light and the particulate first luminescent material light.

7. The light generating device according to claim 1, wherein the light source light has one or more wavelengths in the blue wavelength range; and wherein the first luminescent material light has one or more wavelengths in the red wavelength range.

8. The light generating device according to claim 1, wherein the luminescent element comprises a second luminescent material, different from the particulate first luminescent material, configured to convert at least part of the light source light into second luminescent material light; wherein the device light comprises the first luminescent material light and the second luminescent material light.

9. The light generating device according to claim 8, wherein the second luminescent material light has one or more wavelengths in the green-yellow wavelength range.

10. The light generating device according to claim 8, wherein the second luminescent material comprises a luminescent material of the type A₃B₅O₁₂:Ce, wherein A comprises one or more of Y, La, Gd, Tb and Lu, and wherein B comprises one or more of Al, Ga, In and Sc.

11. The light generating device according to claim 8, wherein the light generating device is configured to generate device light comprising the light source light, the first luminescent material light, and the second luminescent material light.

12. The light generating device according to claim 8, wherein the luminescent element comprises a third luminescent material, different from the first luminescent material and different from the second luminescent material, wherein the third luminescent material is configured to convert at least part of the light source light into third luminescent material light; wherein the device light comprises the light source light, the first luminescent material light, the second luminescent material light, and the third luminescent material light; wherein the third luminescent material light has one or more wavelengths in the orange wavelength range; and wherein the device light is white light having a color rendering index value of at least 80; wherein the luminescent element comprises 5-60 wt % of the second luminescent material; and wherein the luminescent element comprises 0.3-20 wt % of the third luminescent material.

13. The light generating device according to claim 12, wherein the light source light has a centroid wavelength selected from the range of 440-480 nm, wherein the first luminescent material light has a centroid wavelength selected from the range of 620-680 nm, wherein the second luminescent material light has a centroid wavelength selected from the range of 530-580 nm, and wherein the third luminescent material light has a centroid wavelength selected from the range of 580-620 nm, wherein the centroid wavelengths mutually differ with at least 10 nm.

14. The light generating device according to claim 1, wherein the support comprises a reflective layer comprising Ag.

15. A lighting device selected from the group of a lamp (1), a luminaire (2), a projector device (3), a disinfection device, a photochemical reactor, and an optical wireless communication device, comprising the light generating device according to claim 1.
